(19) United States
(12) Patent Application Publication
(10) Pub. No.: US 2024/0234354 A1
(43) Pub. Date: Jul. 11, 2024

(54) SEMICONDUCTOR PACKAGE AND METHOD FOR MANUFACTURING THE SAME

(71) Applicants: ND-HI TECHNOLOGIES LAB, INC., TAIPEI CITY (TW); ETRON TECHNOLOGY, INC., HSINCHU (TW)

(72) Inventors: HO-MING TONG, TAIPEI CITY (TW); WEI YEN, TAIPEI CITY (TW); CHAO-CHUN LU, HSINCHU (TW)

(21) Appl. No.: 18/542,032

(22) Filed: Dec. 15, 2023

Related U.S. Application Data
(60) Provisional application No. 63/433,027, filed on Dec. 16, 2022.
(60) Provisional application No. 63/439,604, filed on Jan. 18, 2023.

(51) Int. Cl. H01L 23/00; H01L 25/16

(52) U.S. Cl. CPC H01L 24/08; H01L 24/05; H01L 24/80; H01L 25/167; H01L 2224/05124; H01L 2224/05139; H01L 2224/05144; H01L 2224/05147; H01L 2224/05155; H01L 2224/05157; H01L 2224/05163; H01L 2224/05164; H01L 2224/05166; H01L 2224/05169; H01L 2224/05172; H01L 2224/05173; H01L 2224/05176; H01L 2224/05178; H01L 2224/0518; H01L 2224/05181; H01L 2224/05184; H01L 2224/05609; H01L 2224/05611; H01L 2224/05613; H01L 2224/05616; H01L 2224/05618; H01L 2224/05624; H01L 2224/05639; H01L 2224/05644; H01L 2224/05647; H01L 2224/05663; H01L 2224/08145; H01L 2224/80224; H01L 2224/80895; H01L 2224/80896

(57) ABSTRACT

A semiconductor package is provided. The semiconductor package includes a first die having a plurality of first metal pads at a first bonding side and a second die over the first die, having a plurality of second metal pads at a second bonding side facing the first bonding side. Each of the first metal pads corresponds to each of the second metal pads with a pitch no greater than about 10 μm. The semiconductor package further includes a first dielectric layer surrounding and in contact with a sidewall of the first metal pads and a second dielectric layer surrounding and in contact with a sidewall of the second metal pads. A method for manufacturing a semiconductor package is also provided.

### PRIORITY CLAIM AND CROSS-REFERENCE

This application claims the benefit of prior-filed U.S. provisional application No. 63/433,027, filed on Dec. 16, 2022, and U.S. provisional application No. 63/439,604, filed on Jan. 18, 2023, and incorporates by reference herein in its entirety.

### FIELD

Present disclosure relates in general to semiconductor packages, and more particularly to semiconductor packages with an ultrafine pitch scale, which is suitable for the application of micro-LED packaging or similar semiconductor structures that have an ultrafine pitch or small die size.

### BACKGROUND

Self-emissive, inorganic micro-LEDs are poised to replace mainstream OLED technology as the dominant and disruptive display technology of the future. In comparison to OLED, micro-LEDs offer significant advantages, including much higher brightness (30×) and energy efficiency, longer product lifespan, and faster switching speeds (in nanoseconds, comparable to semiconductors). Micro-LEDs are typically defined as substrate-less epi-layer LEDs with a length or width dimension of less than 50 μm (sometimes less than 10 μm) and a thickness of approximately 5-7 μm. Although the market for micro-LEDs is currently small, it is projected to experience exponential growth, reaching approximately US$40 million in 2023 and expanding to a total addressable market (TAM) of around US$1.3 billion by 2027. This growth could potentially be even higher if challenges related to mass transfer can be successfully resolved.

There are two approaches to assembling micro-LEDs on receiving substrates or driver IC substrates: (1) mass transfer (i.e., massively parallel transfer) and (2) monolithic array hybridization (MAH). In the MAH approach, a standard LED wafer is etched to form micro-LEDs and then integrated with the receiving driver IC substrate. Although the MAH approach possesses advantages such as a very small pixel size and mass transfer efficiency due to wafer-level integration, it suffers from shortcomings such as small display sizes for VR/AR/MR applications, which is limited by wafer sizes, and the inability to rework defective pixels, which negatively impacts yield.

Currently, mainstream micro-LED processes rely on various mass transfer technologies for high-volume consumer applications, including TV, smartphones, smartwatches, and consumer virtual reality (VR). Referring to FIG. 1, these applications require a pixel density of around 1,500 pixels per inch (PPI) or less, as well as a sub-pixel size of greater than 6 μm. More demanding applications such as augmented reality (AR)/mixed reality (MR) can require a PPI as high as >2,000 and a sub-pixel size as small as <4 μm. FIG. 2 compares mainstream micro-LED mass transfer technologies comprising laser-assisted mass transfer (LAMT), fluidic assembly, electrostatic, elastomer stamp, and roll-to-roll in terms of their key attributes and pros and cons. Among these mass transfer technologies, LAMT surpasses others in terms of speed, repeatability, relatively easy defect management, and extendibility to ultrafine pixel/sub-pixel sizes smaller than 10 μm. LAMT also offers promises to encroach on the higher-pixel-density PPI VR/AR territory, which is believed by many to be reserved for MAH.

LAMT is a massively parallel chip placement technology. Following chip placement, micro-LEDs and receiving substrate structures can be bonded. FIG. 4 illustrates structures, materials and dimensions of some examples of the assembly of micro-LED and receiving substrate, but LAMT is not limited to operating based on these examples. FIGS. 3A and 3B provide an example of the LAMT process. As shown in FIG. 3A, a plurality of micro-LEDs 902 are positioned on a source substrate 900, with some of these micro-LEDs 902 identified as defective micro-LED 902A through optical tests, wafer-level photoluminescence (PL)-based testing, electroluminescence (EL) testing and/or design for test for known-good micro-LED. These micro-LEDs 902, including the defective micro-LEDs 902A, are transferred to a UV transfer tape 904 as a temporary carrier using a conventional laser lift-off process which involves illuminating the sapphire substrate 900 from the substrate side using a laser at a wavelength of, for instance, 266 nm to release the micro-LEDs (902 and 902A). A portion of the micro-LEDs 902 may dislodge during the lift-off operation, resulting in one or more missing blocks 902B on the UV transfer tape 904.

Following tape transfer, the micro-LEDs are then transferred by contacting the tape substrate with a glass carrier or a suitable substrate with a release layer (comprising a release layer, or a release layer plus an adhesion layer comprising organics such as polyimides or silicones) which imparts a stronger adhesion to micro-LEDs compared to the adhesion provided by the transfer tape, and which is release-able with a laser of a suitable wavelength in subsequent processing.

Subsequently and referring to FIG. 3B, a single-beam UV laser at a wavelength of, for instance, 355 nm is then directed at the defective die (902A and 902B) through the backside of the glass to generate gases that create a blister in the release layer, thereby enabling the downward force exerted by the blister along with the gravitational force to eject the defective die from the glass carrier supporting the micro-LEDs. Following defective die removal from the glass carrier, the glass carrier is then aligned with a receiving substrate 932 with known-good sites and the same laser is then switched to the multi-beam mode by invoking the diffractive optical element using a x-y laser scanner to rapidly place good micro-LEDs across a 10 to 300 μm gap onto the known-good sites of the receiving substrate 932. Missing micro-LEDs are then filled in by aligning and ejecting orphaned good micro-LEDs on the glass substrate onto the receiving substrate 932 by invoking the single-beam UV operation set forth.

LAMT can achieve a spot size as small as <20 μm and transfer an exceptionally high number of micro-LEDs in a short time (e.g., >100 million units/hour as shown in FIG. 1) with a placement accuracy as high as ±1.5 μm. Typically, referring to FIG. 3C, a fine-pitch micro-LED 910 includes a substrate 912 (primarily 4-inch or 6-inch sapphire wafers, though 8-inch sapphire and 8-inch silicon are gaining traction), an n-type semiconductor layer 914 (e.g., n-GaN) over the substrate 912, a p-type semiconductor layer 916 (e.g., p-GaN), and an intermediate layer 918 (e.g., InGaN/GaN MQWs) between the n-type semiconductor layer 914 and the p-type semiconductor layer 916. In addition, a p-electrode 920 and a n-electrode 922 can be disposed over the p-type semiconductor layer 916 and the n-type semiconductor layer 914, respectively. In some embodiments, a current spreading layer 924 can be disposed between the p-type semiconductor layer 916 and the p-electrode 920. In some embodiments, a cap or bonding layer 926 (e.g., Ni/Au) can be deposited over the p-electrode 920 and the n-electrode 922.

Following chip placement, chip bonding to the receiving substrate is typically achieved by flip chip bonding based on solder bumps such as In or Cu/Sn as shown in FIG. 4.

FIG. 4 shows a table that summarizes key structures and materials involved in flip chip assembly of micro-LEDs on the receiving substrate for sub-pixel pitches typically higher than 30 μm which are extracted from in references (1) to (7): (1) X. X. Ji et al, “Fabrication And Mechanical Properties Improvement Of Micro Bumps For High-resolution Micro-LED Display Application”, IEEE Transactions on Electron Devices, 2022; (2) Z. J. Liu et al, “360 PPI Flip-chip Mounted Active Matrix Addressable Light Emitting Diode On Silicon (LEDoS) Micro-displays”, Journal of Display Technology, IEEE, 2013; (3) X. X. Ji et al, “Simulation Study On Thermal Mechanical Properties Of 4×4 Micro-LED Array In Flip-chip Bonding Process”, IEEE, 2021; (4) X. Zhang et al, “Active Matrix Monolithic LED Micro-display Using GaN-on-Si Epilayers”, IEEE Photonics Technology Letters, 2019; (5) R. H. Horng et al, “Development And Fabrication Of AlGaInP-based Flip-chip Micro-LEDs”, Journal of the Electron Devices Society, 2018; (6) Z. Gong et al, “Efficient Flip-chip InGaN Micro-pixellated Light-emitting Diode Arrays: Promising Candidates For Micro-displays and Colour Conversion”, Journal of Physics D: Applied Physics, 2008; and (7) L. H. Qi et al, “848 PPI High-brightness Active-matrix Micro-LED Micro-display Using GaN-on-Si Epi-wafers Towards Mass Production”, Optics Express, 2021. As can be seen in FIG. 4, the device dimensions (i.e., sub-pixel chip size, sub-pixel pitch, etc.) are all greater than the micro-LED embodiments to be disclosed herein (see below).

### SUMMARY

It is one aspect of the present disclosure to provide a semiconductor package, including a first die having a plurality of first metal pads at a first bonding side and a second die over the first die, having a plurality of second metal pads at a second bonding side facing the first bonding side. Each of the first metal pads corresponds to each of the second metal pads with a pitch no greater than about 10 μm. The semiconductor package further includes a first dielectric layer surrounding and in contact with a sidewall of the first metal pads and a second dielectric layer surrounding and in contact with a sidewall of the second metal pads.

It is another aspect of the present disclosure to provide a semiconductor package, including a first die, a second die disposed over the first die, and a bonding layer between the first die and the second die. The bonding layer includes a plurality of first metal pads, a plurality of second metal pads, and a soft metal (SM) section or a solder section. Each of the plurality of first metal pads is stacked with a first barrier layer and connected to the first die, and a first dielectric bonding material contacts a sidewall of each of the plurality of first metal pads and a sidewall of the first barrier layer. Each of the plurality of second metal pads is stacked with a second barrier layer and connected to the second die, and a second dielectric bonding material contacts a sidewall of each of the plurality of second metal pads and a sidewall of the second barrier layer. The soft metal (SM) section or the solder section is between each of the first metal pads and each of the second metal pads.

It is another aspect of the present disclosure to provide a method for manufacturing a semiconductor package. The method includes (1) receiving a first substrate and a second substrate; (2) forming a first bonding layer on the first substrate where the first bonding layer includes a plurality of first dielectric bonding blocks and a plurality of first metal pads laterally and alternatively arranged with the plurality of first dielectric bonding blocks; and a plurality of first soft metal (SM) or solder layers, each over one of the first metal pads, wherein an upper surface of the first SM or solder layer is recessed from an upper surface of the first dielectric bonding blocks. (3) Forming a second bonding layer on the second substrate, wherein the second bonding layer includes a plurality of second dielectric bonding blocks and a plurality of second metal pads laterally and alternatively arranged with the plurality of second dielectric bonding blocks; (4) self-aligning at least a die region on the second substrate to a corresponding die region on the first substrate by aligning and contacting the first dielectric bonding blocks to the second dielectric bonding blocks under room temperature; and (5) elevating a temperature of the plurality of first SM or solder layers by performing a laser heating operation.

### BRIEF DESCRIPTION OF THE DRAWINGS

Aspects of the present disclosure are best understood from the following detailed descriptions when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a development curve of pixel pitch and pixel density.

FIG. 2 illustrates a table for comparing the pros and cons of some micro-LED mass transfer technologies.

FIGS. 3A and 3B illustrate top views of a process of a plurality of micro-LEDs transferred under the laser-assisted mass transfer technique.

FIG. 3C illustrates a cross-sectional view of a micro-LED.

FIG. 4 illustrates a table summarizing examples of flip chip assembly of micro-LED and receiving substrate showing structures, materials and dimensions.

FIG. 5 illustrates a cross-sectional view of the process to eject a micro-LED by creating a blister in a release layer with a laser.

FIG. 6 illustrates a cross-sectional view of a semiconductor package according to some embodiments of the present disclosure.

FIG. 7 illustrates a cross-sectional view of a semiconductor package according to some embodiments of the present disclosure.

FIGS. 8A to 8D illustrate process of manufacturing a semiconductor package according to some embodiments of the present disclosure.

FIG. 9 illustrates a process of transferring and ejecting micro-LEDs according to some embodiments of the present disclosure.

FIG. 10 illustrates a process of transferring and ejecting micro-LEDs according to some embodiments of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

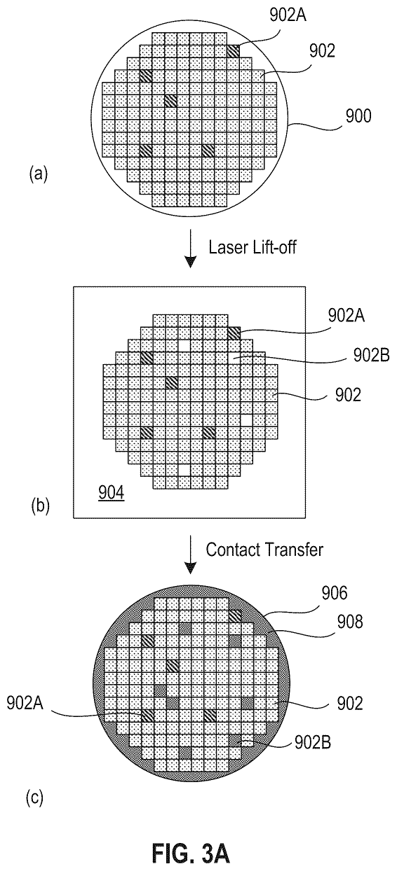

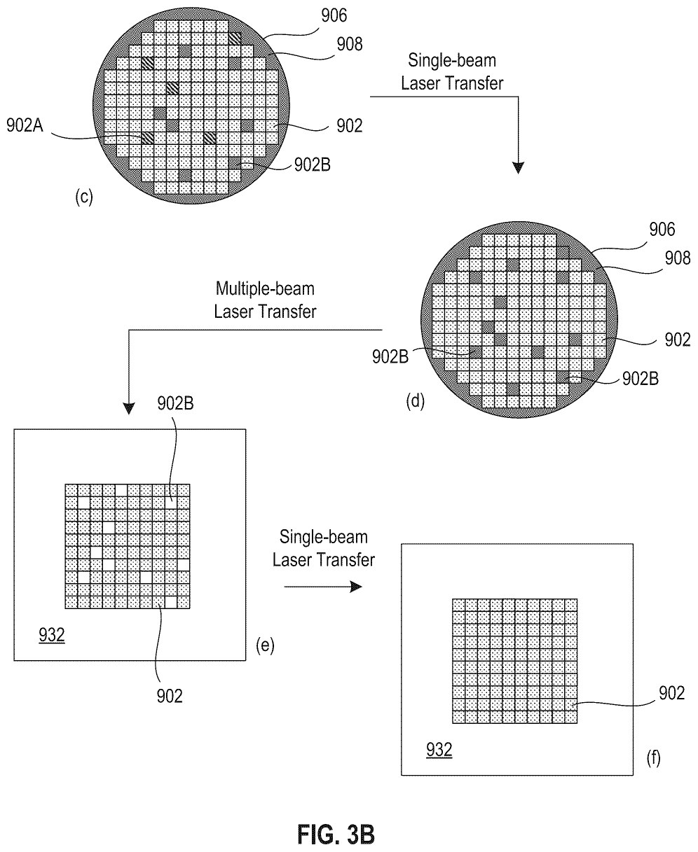

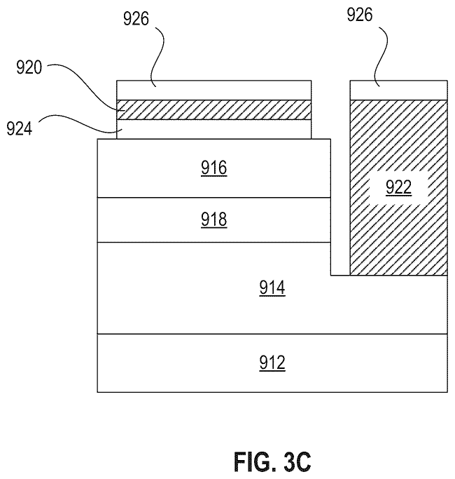

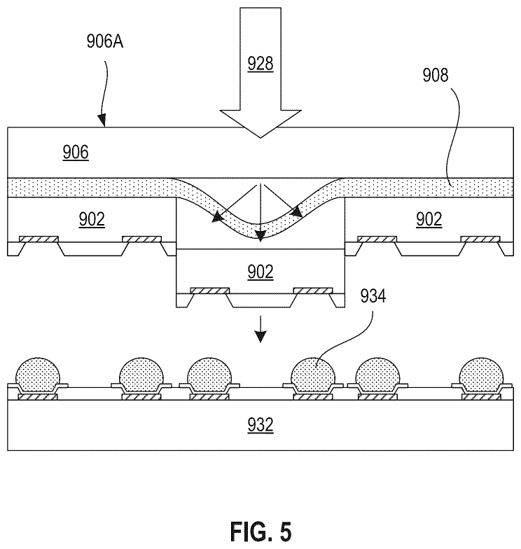

Referring to FIG. 5, based on the micro-LED wafer map (see FIGS. 3A and 3B) showing a plurality of good and defective micro-LEDs (dies) 902, a single-beam, UV laser 928 is directed at the defective micro-LEDs through a backside 906A of the glass carrier 906. This UV laser 928 at a wavelength of, for instance, 355 nm, can generates gases that create a blister in the release layer 908, enabling the downward force exerted by the blister and the gravitational force to remove the defective micro-LED from the glass carrier 906 supporting the micro-LEDs 902.

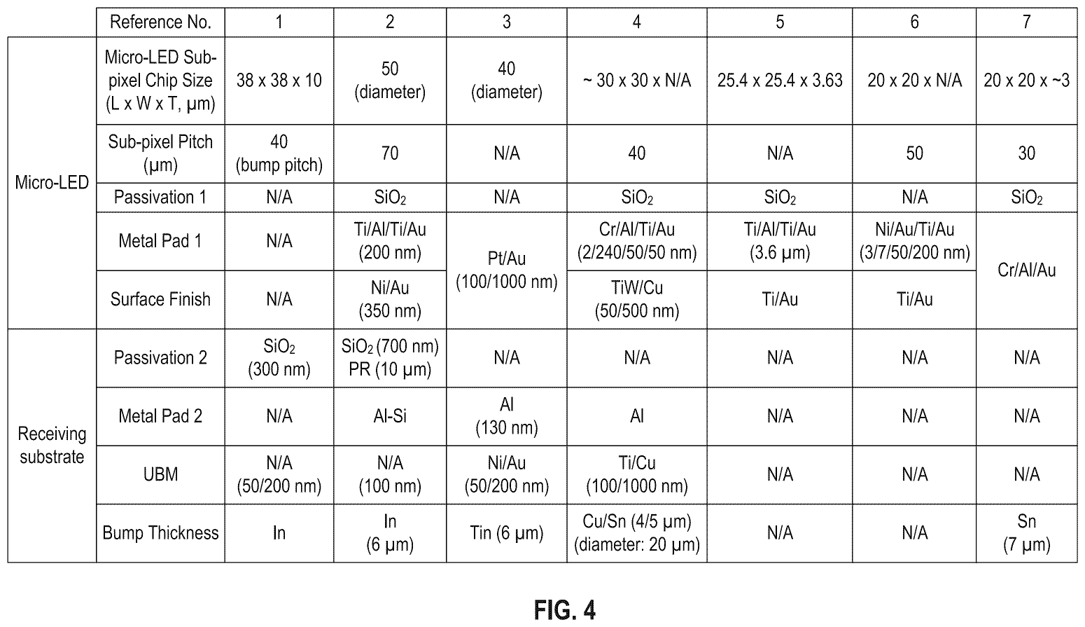

Referring back to the process shown in FIG. 3B, after removing the defective micro-LEDs from the glass carrier 906, the glass carrier 906 (not shown in FIG. 3B) is aligned with a receiving substrate 932 with known-good sites as illustrated in FIG. 5. The UV laser 928 is then switched to the multi-beam mode by invoking the diffractive optical element. This is done using the same laser used in ejecting defective dies, as well as an x-y laser scanner, to rapidly place good micro-LEDs across a 10 to 300 μm gap onto the receiving substrate 932. The UV laser 928 may generate gases that create blisters in the release layer 908, enabling the downward force to remove the good micro-LEDs 902 from the glass carrier 906 and towards the known-good sites of the receiving substrate 932. This ejection operation may incur yield loss due to the fact that the good micro-LEDs 902 may bounce off the receiving substrate 932 or be misaligned with the receiving substrate 932 by colliding with the solder bumps 934 protruded from the receiving substrate 932 (see FIGS. 5 and 4). The receiving substrate 932 here can be a display panel with driver circuits, or a driver IC wafer. Furthermore, as shown in step (f) in FIG. 3B, the missing micro-LEDs are filled in by aligning orphaned good micro-LEDs on glass carriers with the receiving substrate 932 and using the UV laser 928 in the aforementioned single-beam mode to drop good micro-LEDs (i.e., the good dies) onto the receiving substrate 932.

Following chip placement, chip bonding to the receiving substrate 932 is typically achieved through flip chip bonding using solder bumps 934 (see FIG. 5), such as In or Cu/Sn as shown in FIG. 4, for sub-pixel pitches typically exceeding 30 μm. Flip chip bonding commonly utilizes heat to melt the solder, preferably in an inert atmosphere such as nitrogen (N₂) or vacuum, or in a reducing atmosphere like formic acid. Indium (In), with a melting point of 156.6° C., can replace tin (Sn) with a melting point of 231.9° C., enabling the use of lower bonding temperatures to minimize thermal expansion mismatch effects between the micro-LEDs 902 and the receiving substrate 932. During solder reflow, the reflowed solder bumps 934 are expected to wet the metal pads and/or surface finish on the good micro-LEDs 902 and form permanent bonds.

Misalignment between the micro-LEDs and the receiving substrate creates bonding yield problems, which along with the aforementioned micro-LED bounce-off during chip placement tend to lower the overall yields. The situation is aggravated as a dimension of micro-LEDs gets smaller, particular to <10 μm.

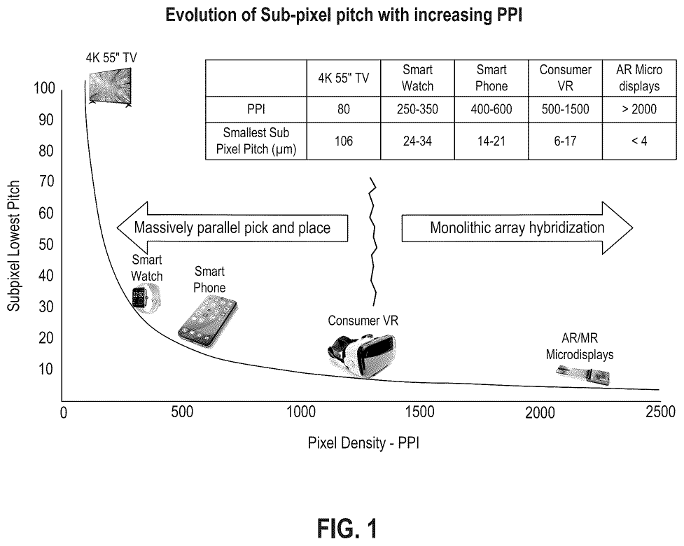

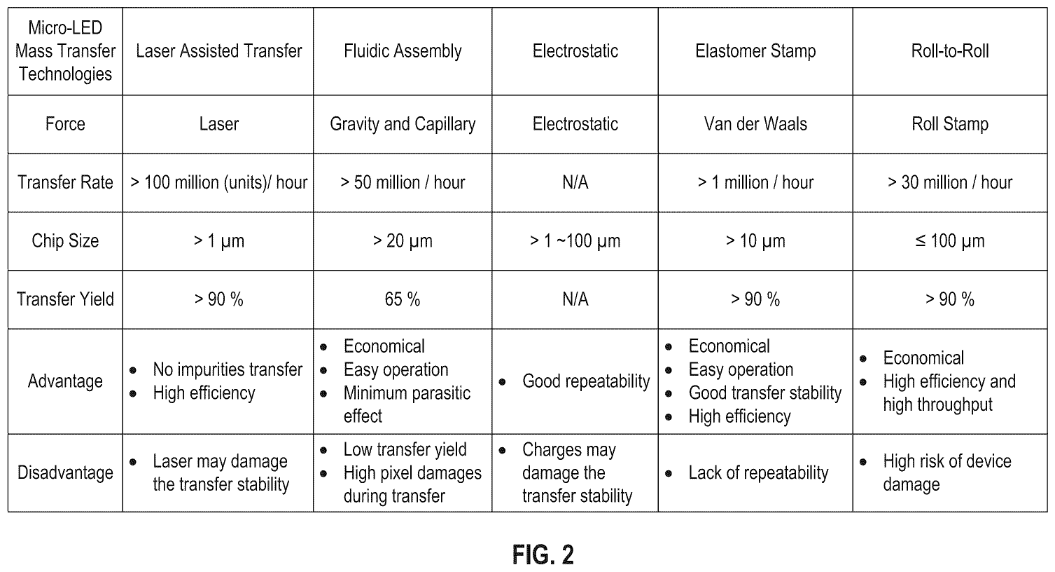

To advance LAMT, significant manufacturing challenges must be confronted head-on. These challenges primarily include achieving (1) a reliable, high massively parallel chip placement yield; and (2) a reliable, high bonding yield following chip placement (both of which are addressed by the present invention). Both challenges involve handling millions of ultra-tiny, imperceptible micro-LEDs simultaneously in a single process step with minimal chip displacements. This becomes increasingly critical as chip and micro-LED sizes continue to miniaturize from today's ˜55×32×6 μm to 10 μm or smaller (see FIGS. 1 and 2), and as pixel numbers escalate. While flip chip has been the preferred technology for high-end processor applications requiring fine pitches based on copper pillar micro-bumps, challenges arise for smaller pixel sizes and correspondingly smaller bond pitches. This is particularly crucial in applications like VR/AR/MR (see FIG. 2), where small displays and high pixel densities demand almost 100% placement and bonding yield during assembly.

While intensive efforts have been focused on mass transfer or chip placement of micro-LEDs, less attention has been given to minimizing chip displacements after mass transfer and subsequent bonding. The present disclosure aims to significantly enhance not only the chip placement/alignment yield but also the bonding yield simultaneously, using either of the following two approaches: (1) self-aligned, laser-assisted localized flip chip bonding (LALF); and (2) wafer-to-wafer mass transfer (W2WM). Both technologies rely on LAMT and dielectric-to-dielectric bonding and enable the ongoing miniaturization of micro-LEDs and ultra-fine bonding pitches to 10 μm and below, compared to 40 μm and higher for flip chip. Laser heating is also highly advisable in order to achieve high yields for both the LALF and W2WM approaches involving ultrafine pitches/dimensions.

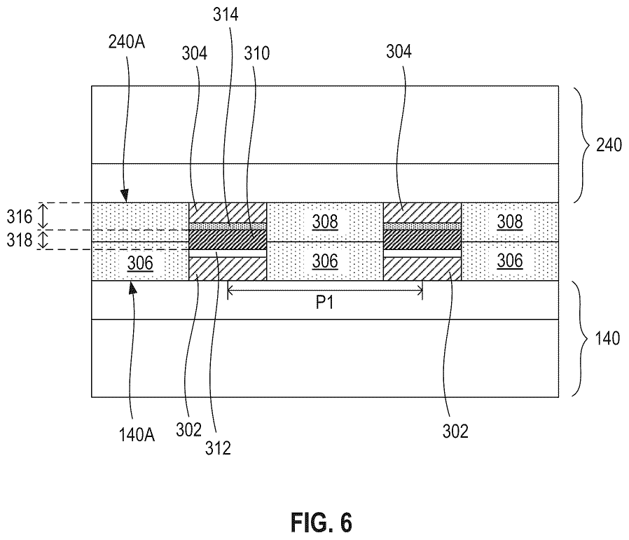

Accordingly, the semiconductor package in the present disclosure is suitable for packaging under ultrafine pitch conditions using flip chip assembly of micro-LEDs on a receiving substrate for demonstration, while in some embodiments, the semiconductor package may involve chips or chiplets requiring ultrafine-pitch bonding for other types applications such as high-performance computing, data centers, artificial intelligence and RF/5G/6G/millimeter wave. Referring to FIG. 6, in some embodiments, the semiconductor package includes a first die 140 and a second die 240 disposed over the first die 140. The second die 240 can be a micro-LED die, a processor die, or a chiplet, while the first die 140 can be a driver IC die or a portion of a display panel. In some embodiments, such driver IC die or display panel can be used to control the second die 240, such as the micro-LED die.

In some embodiments, the first die 140 has a plurality of first metal pads 302 at a first bonding side 140A. The second die 240 has a plurality of second metal pads 304 at a second bonding side 240A facing the first bonding side 140A. In some embodiments, since the present disclosure is suitable for IC packaging applications under ultrafine pitch conditions, each of the first metal pads 302 corresponds to each of the second metal pads 304 may be characterized by a pitch P1 no greater than about 10 μm with adjacent pads. In some embodiments, the size of the packaged semiconductor structure is also small, for instance, a dimension of the second die 240 can be less than about 10 μm by 10 μm. In some embodiments, a dimension of the first die 140 can also be less than about 10 μm by 10 μm. Furthermore, in some embodiments, the size of the metal pads of the first die 140 and/or the second die 240 is also small, for instance, a dimension (e.g., diameter or length) of each of the first metal pads 302 and a dimension of each of the second metal pads 304 are, respectively, less than about 10 μm.

In some embodiments, the semiconductor package further includes a first dielectric layer 306 (see FIG. 6) surrounding and in contact with a sidewall of the first metal pads 302; and a second dielectric layer 308 surrounding and in contact with a sidewall of the second metal pads 304. In some embodiments, the material of the first dielectric layer 306 and the second dielectric layer 308 includes silicon dioxide (SiO₂) or polymer (e.g., polyimide or polybenzoxazole). In some embodiments, the first dielectric layer 306 and the second dielectric layer 308 are composed of fully-cured polymer.

As shown in FIG. 6, a plurality of conductive paths between the first die 140 and the second die 240 are formed through bonding of the first metal pads 302 and the second metal pads 304, while the first metal pads 302 and the second metal pads 304 are not directly in contact with each other, but electrically connected by additional conductive materials. In some embodiments, the semiconductor package further includes a soft metal (SM) section or a solder section 310 between each of the first metal pads 302 and the second metal pads 304. In some embodiments, a sidewall of the SM section or the solder section 310 is in contact with the first dielectric layer 306 and/or the second dielectric layer 308. In some embodiments, a melting point of the SM section or the solder section 310 is no greater than about 250° C. In some embodiments, the material of the SM or solder section 310 may include Sn—Ag alloy (Sn/Ag), Sn—Ag—Cu alloy (Sn/Ag/Cu), gold (Au), indium (In), eutectic Sn—Bi alloy (Sn/Bi), etc. wherein indium (In) is the softest metal with a melting point of 157° C., and eutectic Sn—Bi alloy has a low melting point of 138° C.

In some embodiments, a thickness of each of the SM section or the solder section 310 is in a range of from about 1 μm to about 2 μm.

In some embodiments, the SM section or the solder section 310 may further include a barrier layer and/or a wetting layer at its interfaces with the first metal pads 302 and the second metal pads 304. For instance, as shown in the figure, each of the plurality of first metal pads 302 is stacked with a first barrier layer 312 and connected to the first die 140, and the first dielectric bonding layer 306 is in contact with the sidewall of each of the plurality of first metal pads 302 and a sidewall of the first barrier layer 312. Likewise, each of the plurality of second metal pads 304 is stacked with a second barrier layer 314 and connected to the second die 240, and the second dielectric bonding layer 308 is in contact with the sidewall of each of the plurality of second metal pads 304 and a sidewall of the second barrier layer 314.

In some embodiments, each of the first barrier layers 312 and the second barrier layers 314 includes nickel (Ni), nickel vanadium (NiV), titanium (Ti), titanium tungsten (TiW), titanium nitride (TiN), tantalum (Ta), tantalum nitride (TaN), chromium (Cr), phased chromium-copper (Cr/Cu), and their combinations. In some embodiments, each of the first barrier layers 312 and/or the second barrier layers 314 is coated with a wetting layer including Au, Ag, Pd, or a combination of metals comprising copper (Cu), nickel (Ni), nickel vanadium (NiV), gold (Au), or silver (Ag) while the SM section or the solder section 310 further includes a die attachment materials made up of tin (Sn), lead (Pb), gold (Au), silver (Ag), copper (Cu), indium (In), bismuth (Bi), zinc (Zn), aluminum (Al), thorium (Th), or their combinations.

In the structure profile aspect, in some embodiments, a sidewall of the SM section or the solder section 310 is aligned with a sidewall of one of the first metal pads 302 or the second metal pads 304. Unlike the conventional bumping approach that employs solder as the conductive material, followed by the later application of underfilling material to encapsulate the solder joints between the bumped die and the substrate, the SM section or the solder section 310 in the present disclosure is created with a recess under the surface of the first dielectric layer 306 and/or the second dielectric layer 308 prior to a bonding operation. Consequently, the profile of the SM section or the solder section 310 should correspond to the profile of the etched sidewall of the first dielectric layer 306 and/or the second dielectric layer 308. In some embodiments, since the recess within the first dielectric layer 306 or the second dielectric layer 308 may have a substantially tapered, curved, or straight profile, the sidewall of the SM section or the solder section 310 also has a corresponding profile. In other embodiments, the two sidewalls of the recess may have curved profiles from a cross-sectional perspective. The recessed structures enable easier chip placement, which in conjunction with self-aligned dielectric-to-dielectric (e.g., oxide-to-oxide) bonding, increase chip placement and final bonding yields using LAMT.

Still referring to FIG. 6, in some embodiments, a first segment 316 of a sidewall of the second dielectric layer 308 proximal to the second die 240 is in contact with a sidewall of the second metal pad 304, and a second segment 318 of the sidewall of the second dielectric layer 308 proximal to the first die 140 is in contact with a sidewall of the SM section or the solder section 310. In some embodiments, a height ratio of the second segment 318 and the first segment 316 is in a range of from 25% to 85%.

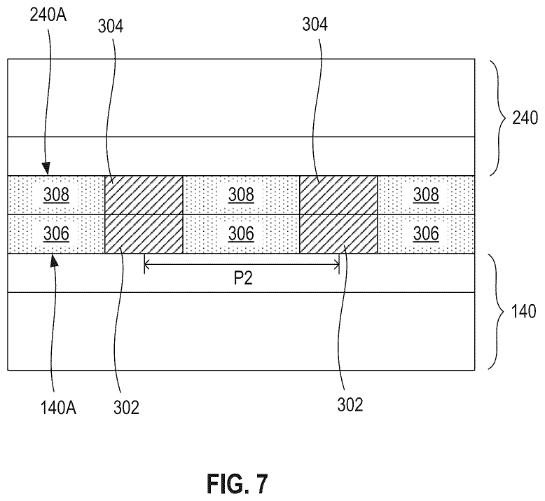

Referring to FIG. 7, in some embodiments, no SM section nor the solder section is involved between the first die 140 and the second die 240. In these embodiments, the first metal pads 302 are directly in contact with the second metal pads 304, wherein each of the first metal pads 302 corresponds to each of the second metal pads 304 is characterized by a pitch P2 no greater than about 10 μm with adjacent pads. The semiconductor package illustrated in FIG. 7 serves as an example of an ultrafine pitch structure where the technical challenge to achieve successful bonding of the first die 140 and the second die 240 is higher compared to bonding involving the SM section or the solder section 310.

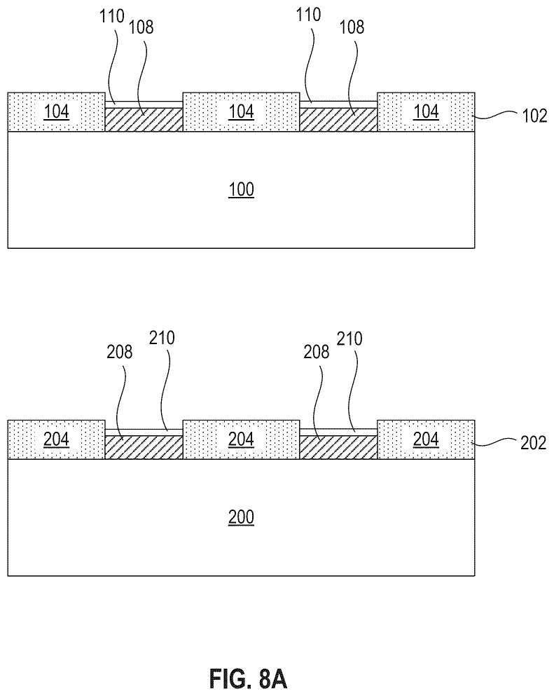

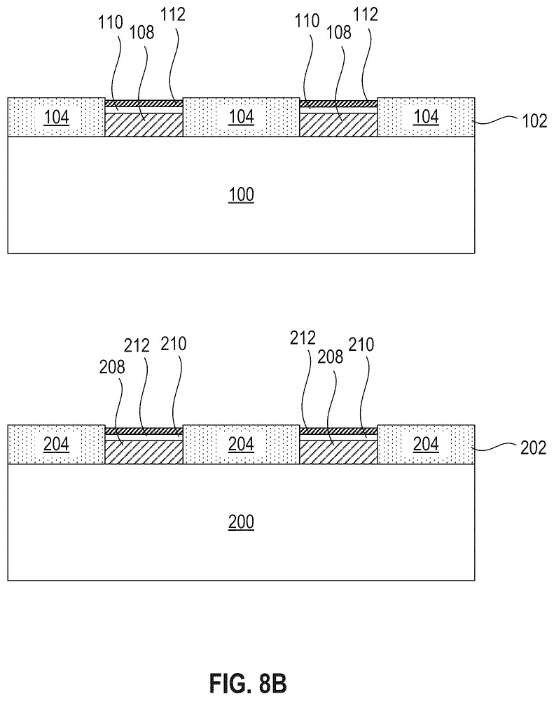

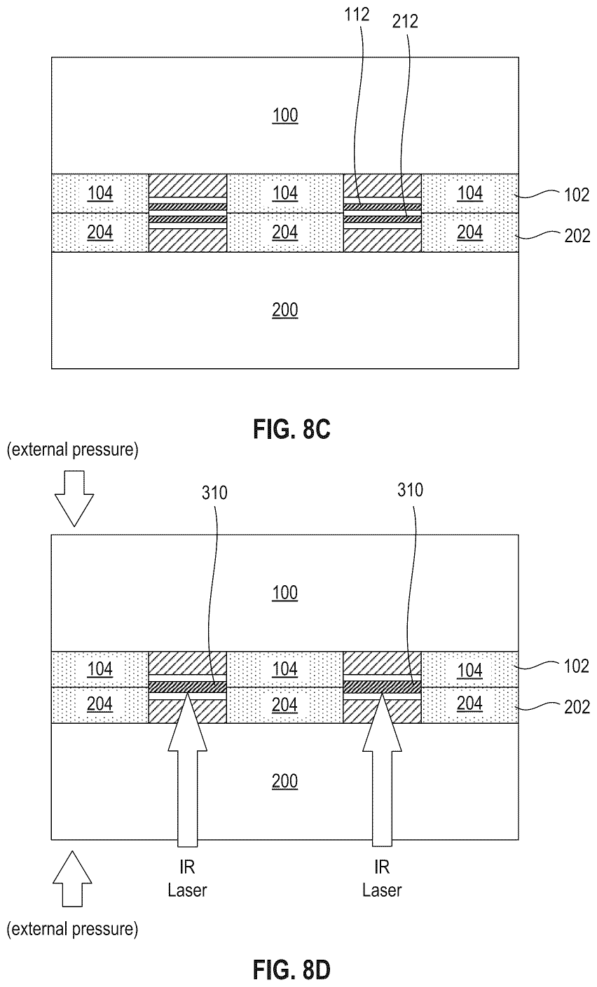

An example process to create the semiconductor structure as shown in FIG. 6 can be seen in FIGS. 8A to 8D. As shown in FIG. 8A, the self-aligned, laser-assisted localized flip chip bonding (LALF) approach may include the following operations: receiving a first substrate 100 and a second substrate 200; and forming a first bonding layer 102 on the first substrate 100 and a second bonding layer 202 on the second substrate 200, respectively.

In some embodiments, the first substrate 100 and the second substrate 200 can be the driver IC substrate and the micro-LEDs, respectively (and vice versa), and one of them can be a rigid or flexible substrate with circuits, such as that used in wearables.

In some embodiments, each of the first bonding layer 102 and the second bonding layer 202 is a combination of dielectric materials and conductive pads for bonding. As shown in FIG. 8A, the first bonding layer 102 includes a plurality of first dielectric bonding blocks 104 and a plurality of first metal pads 108 laterally and alternatively arranged with the plurality of first dielectric bonding blocks 104. In some embodiments, the material of the first dielectric bonding blocks 104 includes silicon dioxide (SiO₂) or polymer (e.g., polyimide or polybenzoxazole), while the material of the first metal pads 108 include copper (Cu), gold (Au), aluminum (Al), tungsten (W), molybdenum (Mo), rhodium (Rh), cobalt (Co), ruthenium (Ru), iridium (Ir), platinum (Pt), palladium (Pd), Osmium (Os), or combinations thereof. Furthermore, as shown in the figure, each of the first metal pads 108 is recessed from the adjacent first dielectric bonding blocks 104, and hence a thickness of the first dielectric bonding blocks 104 is greater than a thickness of the first metal pad 108.

Likewise, the second bonding layer 202 includes a plurality of second dielectric bonding blocks 204 and a plurality of second metal pads 208 laterally and alternatively arranged with the plurality of second dielectric bonding blocks 204. The material of the second dielectric bonding blocks 204 and the material of the second metal pads 208 can be identical to that of the first dielectric bonding blocks 104 and the first metal pads 108, respectively. Moreover, each of the second metal pads 208 is recessed from the adjacent second dielectric bonding blocks 204, and hence a thickness of the second dielectric bonding block 204 is greater than a thickness of the second metal pad 208.

In some embodiments, a pitch of the first metal pads 108 and a pitch of the second metal pads 208 are both no greater than about 10 μm. In some embodiments, each of these recessed (or dished) metal pads (from the surface of the dielectric bonding blocks) can contain a thin barrier layer. For instance, a first barrier layer 110 and a second barrier layer 210 can be coated on the first metal pads 108 and the second metal pads 208, respectively. In some embodiments, the first barrier layers 110 and/or the second barrier layers 210 can further be coated with a wetting layer including Au, Ag, Pd, or a combination of metals comprising Cu, Ni, NiV, Au, or Ag. In some examples, the material of the barrier/wetting layer options can include Ti/NiV/Au, Ti/Ni/Ag, Ti/Ag, Ti/Au, Ti/Ni/Au, Ti/NiV/Au, Ti/NiV/Ag and Ti/TiW/Au.

In some embodiments, the recessed metal pads on one of the substrates (e.g., the first substrate 100, which can include a plurality of driver ICs) is coated with the barrier layer and the wetting layer, while another substrate (e.g., the second substrate 200, which can include a plurality of micro-LEDs) can be coated with a barrier layer (e.g., Ni or Ti), a wetting layer (e.g., Au) and a soft metal or solder material (e.g., a second solder layer 212).

Referring to FIG. 8B, in some embodiments, a plurality of first soft metal or solder layer 112 can be formed over the first metal pads 108, wherein an upper surface of the first soft metal or the first solder layer 112 is recessed from an upper surface of the first dielectric bonding blocks 104. Likewise, the solder layer can be formed over the second substrate 200 and a plurality of second soft metal or second solder layer 212 are formed over the second metal pads 208, wherein an upper surface of the second soft metal or second solder layer 212 is recessed from an upper surface of the second dielectric bonding blocks 204. In some embodiments, the solder layer is only formed over one of the substrates instead of both of the substrates. In addition, since the pitches of the first metal pads 108 and the second metal pads 208 are small, the first solder layer 112 and the second solder layer 212 can be formed by plating. In some embodiments, a thickness of the first solder layer 112 and a thickness of the second solder layer 212 are in a range of from about 1 μm to about 2 μm. In some embodiments, a material of the soft metal or solder layer 212 can include In, Cu/Sn, Sn, Sn—Ag, Sn—Ag—Cu, or tin-bismuth (Sn—Bi). The second solder layer 212 in the second substrate 200 can be used to bond the second metal pads 208 to the first metal pads 108, while the first dielectric bonding blocks 104 and the second dielectric bonding blocks 204 serve as the bonding layer for self-aligned dielectric-to-dielectric bonding.

Referring to FIG. 8C, in some embodiments, at least a die region on the second substrate 200 is self-aligned to a corresponding die region on the first substrate 100 by aligning and contacting the first dielectric bonding blocks 104 to the second dielectric bonding blocks 204 under room temperature. Furthermore, in some embodiments, a surface of the plurality of first dielectric bonding blocks 104 and a surface of the plurality of second dielectric bonding blocks 204 are planarized, activated and wetted with de-ionized water prior to self-aligning the first substrate 100 to the second substrate 200 upon contacting the first dielectric bonding blocks 104 to the second dielectric bonding blocks 204 at room temperature.

Oxide-to-oxide-based dielectric-to-dielectric bonding can achieve a copper-to-copper bond pitch as small as 1 μm or less based on a 300-mm wafer-to-wafer bond. Therefore, it is well-suited for bonding ultra-tiny micro-LED chips with ultrafine pitches to driver IC substrates. More importantly, it can scale with micro-LED chip or sub-pixel sizes down to a few micrometers or less for even the most stringent VR/AR/MR applications requiring a PPI in excess of 1,500 (see FIG. 2). The state-of-the-art system for 300 mm wafer bonding machines can deliver an overlay alignment accuracy within 195 nm (3 sigma) overall, with the mean alignment centered below 15 nm. The presence of a softer solder layer, compared to copper, in one substrate (or both substrates) can significantly widen process windows and enhance bonding yields.

As mentioned earlier, the surfaces of the first dielectric bonding blocks 104 and the second dielectric bonding blocks 204 undergo surface pre-treatment (planarization, activation, and wetting) before aligning and contacting the first substrate 100 and the second substrate 200 using LAMT. The pre-treatment process may involve: (a) conducting a chemical mechanical polishing (CMP) operation to achieve a surface roughness, preferably with an arithmetic average roughness (RA) or root mean square roughness no greater than about 1 or 0.5 nm for both substrates; (b) executing a wet surface pre-treating operation involving ultrasonic de-ionized (DI) water clean, H₂SO₄/H₂O₂ treatment, NH₃/H₂O₂ treatment, and N₂ blow dry; (c) performing a surface treatment operation such as plasma treatment, inductively coupled plasma reactive ion etching (ICP-RIE) with O₂, N₂ or H₂/O₂, deep RIE (DRIE) with O₂/CF₄, and/or activation of bonding surfaces using a fast atom beam gun (FAB) with argon neutral atom beam at ˜1 keV, or an ion gun with argon ion at ˜60 eV, to remove oxide films in a vacuum and reveal dangling bonds at the surfaces for bonding; and/or (d) DI water surface pre-wetting.

After surface pre-treatment, again referring to FIG. 8C, the first substrate 100 and the second substrate 200 (complete with water wetting layers) can be aligned, and brought into contact in the LAMT tool. Self-aligned chip placement can then commence automatically under the assistance of, for instance, self-aligned oxide-to-oxide bonding “chemical” forces.

After self-aligned chip placement, referring to FIG. 8D, bonding of the two substrates at low temperatures (e.g., <250° C.) can then be achieved with the use of an infrared (IR) laser under the assistance of bonding stage heating as needed. In some embodiments, a temperature of the first solder layer 112 (see FIG. 8C) and/or the second solder layer 212 (see FIG. 8C) is increased by performing a IR laser heating operation wherein the laser can heat the receiving substrate (e.g., the first substrate 100, such as silicon or a Si-based driver IC). Typically, an IR-absorbing material like silicon can be heated and the heat can be conducted and propagate to heat and melt the first solder layer 112 and/or the second solder layer 212. The heat conduction can cause the reflow of the solder (e.g., the first solder layer 112 and/or the second solder layer 212, labeled in FIG. 8C) into the SM section or the solder section 310 (see FIG. 8D) in the final package. Depending on the applications and materials involved, the laser energy can be absorbed and converted into a local heat source with non-transparent substrate materials such as Si, Poly-Si, GaAs, etc., while with transparent materials such as glass display panel, the laser energy passes through without significant absorption effects and can be directed to heat the solder directly.

For IR laser-assisted soldering and direct bonding, diode lasers in the near-IR spectrum (e.g., 980 nm or 940 nm) are preferred over other IR laser sources such as carbon dioxide (CO₂) and Nd:YAG lasers. Diode lasers offer high efficiency, a long service life, compact size, ease of integration into existing bonding stations, and low maintenance. The most popular commercially available diode laser wavelengths range from 810 nm to 980 nm, although they can extend from 630 nm to 1900 nm. CO₂ lasers produce IR light with a wavelength of 10,600 nm, which is highly absorbed by organic materials, making them less suitable for laser-assisted bonding involving organic substrates. Nd:YAG lasers operate at a wavelength of 1064 nm in the IR spectrum. The near-IR spectrum provided by diode and Nd:YAG lasers is less absorbent in organic materials, less reflective off metal surfaces, and better suited for LALF involving organic substrates.

The laser beam typically emits a conical-shaped beam with the tip of the cone corresponding to the minimum spot size located away from the lens of the laser head optics at its focal distance. By adjusting the distance of laser optics to the workpiece, the spot size can be increased, and the energy can be distributed over a larger area of the workpiece at reduced energy density. In other words, a larger laser spot size, as large as the die (e.g., the driver IC), can be achieved by defocusing the beam, changing the focal distance of high-power diode lasers from the minimum diameter focused spot size. Compared to Nd:YAG lasers, high-power diode lasers have an advantage as they can provide a larger spot size with even energy distribution without overall energy loss due to defocusing.

For diode lasers, two laser modes can be considered for bonding: the step-function mode, utilizing the maximum capacity of the laser output power for fast heating, and the linear mode, raising laser power linearly for more gradual heating. Besides laser mode, irradiation duration, irradiation times, and laser power can also fine-tune the temperature profile of silicon during laser-assisted bonding. For instance, a higher laser power density of 120 W/cm² can be used to heat the silicon for 0.5 seconds to quickly raise the temperature of the die, followed by laser irradiation at 70+ W/cm² for less than 1 second to maintain the silicon temperature for solder reflow. At a usable wavelength of 980 nm using diode lasers, the absorptivity of silicon is 0.57 (57% absorption), whereas the reflectivity and transmissivity are 0.31 and 0.21, respectively. Since the absorptivity of silicon at the 980 nm wavelength is 0.57, the energy transferred to the die from the initial laser irradiation is 120 W/cm²×0.57 (i.e., 68.4 W/cm²).

Upon IR laser irradiation, the incident laser beam is absorbed by the silicon die, creating a uniform temperature profile across the die. Through heat conduction in silicon, the heat is conducted to the solder, melting the solder, and to the dielectric-to-dielectric bond interface, achieving permanent bonding (covalent bond formation) upon solder solidification. Depending on the application, each irradiation can take as little as a few seconds or less per die, and the silicon temperature can reach 250° C. or higher, as needed—higher than the melting point of indium (In) solder (156.6° C.), tin (Sn) (231.9° C.), or Sn 96.5/Ag 3.5 eutectic solder (221° C.). Substrate thicknesses, the number of solder joints, and the bonding stage temperature for pre-heating (e.g., 60° C. to 90° C.) also play a crucial role in optimizing laser mode and conditions.

Using the laser-assisted localized reflow approach, short temperature cycles, precisely controlled local heat input, and a one-time heating of each chip enable bonding with a small edge-to-edge clearance. Non-contact soldering, ease of automation, and integration with bonding stations combine to minimize the risks of surface oxidation and thermo-mechanical stresses caused by thermal expansion mismatch and warpage. Compared to bulky CO₂ and Nd:YAG lasers, which require mounting on a dedicated XYZ linear stage for movement, high-power diode lasers deliver laser energy through a thin and flexible fiber-optic cable attached to a compact optics head. This head can be mounted next to an existing bonding station using the XYZ linear stage already in place.

In some prior approaches, thermo-compression bonding (TCB), typically utilized for fine-pitch flip chip bonding based on Cu pillar micro-bumps, employs a heated bonding head to pick up and contact the die, align the die to the substrate pre-coated with non-conductive paste/film (NCP), and then bond the die to the substrate. However, such prior approach is not suitable for the semiconductor packaging in the present disclosure involving mass transfer and ultrafine pitches/dimensions. For fine-pitch applications, the LALF approach in the present disclosure can avoid problems often encountered by TCB with NCP, including solder extrusion and solder bridging caused by excessive compression forces and bonding conditions. LALF also eliminates the need for NCP. The throughput of LALF can be five times that of the TCB process with NCP.

In some embodiments, a non-laser heating operation, such as those involving the use of a bonding stage, a hot plate or a furnace can be applied to the semiconductor package to achieve a permanent bonding between the first substrate 100 and the second substrate 200 in conjunction with the laser heating operation. After the LALF, electrical contacts may or may not have been established, and gaps between the metal pads may still exist. This necessitates subsequent non-laser heating to form covalent or permanent bonds at the dielectric interfaces and electrical connections between the metal pads. In cases where the material of the first dielectric bonding blocks 104 and the second dielectric bonding blocks 204 is polymer-based, the non-laser heating operation can be performed under the application of an external pressure to the first substrate 100 and second substrate 200. In other embodiments, when the material of the first dielectric bonding blocks 104 and the second dielectric bonding blocks 204 is silicon oxide, the application of an external pressure can be optionally deployed during the non-laser heating operation.

In addition, the localized heating from the IR laser in LALF minimizes displacement effects caused by thermal expansion differences between the two substrates.

Following bonding, in some embodiments, the process may further involve automatic optical inspection, photoluminescence (PL), electroluminescence (EL) testing and encapsulation after bonding. Lasers can then be employed for the removal of defective micro-LEDs and placement of known-good micro-LEDs prior to bonding of the first substrate and the second substrate.

In some embodiments and referring to FIG. 7, the first metal pads 302 and the second metal pads 304 are directly bonded without an intermediate soft metal section or solder section.

In this case, the utilization of nano-twinned and fine-grained copper (as opposed to solder in the LALF approach) can contribute to reducing anneal temperatures to as low as 175° C. This is highly desirable for mitigating thermal expansion mismatch effects, such as alignment and stresses.

The W2WM approach differs from the LALF approach in that the former relies on directly contacting the second substrate containing known-good sites and with corresponding known-good sites of the first substrate, followed by wafer-level release of the known-good sites of the second substrate from the temporary glass carrier with the release layer by scanning a UV laser at the glass carrier—in a fashion similar to IC packaging using fan-out processes. In contrast, in the LALF approach, a multiple-beam laser is used to eject the dies (e.g., micro-LEDs) from the known-good sites of the temporary glass substrate with the releasing layer (e.g., the second substrate) onto the receiving substrate (e.g., the first substrate) at a distance from the receiving substrate.

Both LALF and W2WM involve direct oxide-to-oxide bonding whose process may adhere to a general process sequence as follows, following the aforementioned surface planarization: (1) formation of dangling bonds and bonding between hydroxyl groups and water molecules (resulting from water surface pre-wetting) through plasma activation using gases such as O₂, N₂, and Ar and DI water pre-wetting; (2) self-aligning and bonding of the chip and wafer (or wafer-to-wafer bonding) with oxide bonding layers at room temperature and atmospheric pressure via van der Waals hydrogen bonds between two to three monolayers of water molecules and polar hydroxyl (OH) groups (terminating at both the native and thermal SiO₂ surfaces); (3) formation of van der Waals bonds between H₂O molecules and silanol groups (Si—OH—(H₂O)ₓ—HO—Si; silanol group=Si—OH) on wafer surfaces; and (4) annealing to remove water molecules at the interface and form covalent bonds at temperatures preferably below 250° C.

When necessary, oxide-to-oxide bonding can be carried out on a platform or chuck featuring a flat central zone and an outer annular zone lower than the central zone. The edge portion of a mounted wafer can be biased towards the outer annular zone to disrupt the van der Waals forces (as mentioned in steps (2) and (3) above) at the outer annular zone. This approach establishes an edge gap, allowing water molecules to escape at the wafer edge particularly for the case of wafer-to-wafer (W2W) bonding.

Besides using SiO₂ as the material of the dielectric bonding blocks, dielectric materials can also be nitride based, or polymer based. A case in point is a fully-cured polymer such as a polyimide (PI), which is commonly employed in wafer Back-End-of-Line (BEOL) and advanced System in Package (SiP) wafer-level processes pertaining to wafer-level packaging in general, 2.5D interposers (e.g., silicon or redistribution layer, RDL, interposer) and fan-out structures. For instance, consider fully cured PI-to-PI bonding based on the pyromellitic dianhydride (PMDA) and 4,4′-diaminodiphenyl ether (4,4′-ODA) PI chemistry. Void-free PI-to-PI bonding can be achieved by activating the PI surfaces with oxygen plasma, generating low-density hydrophilic groups on the PI surface. This process effectively enhances the adsorption of water molecules introduced by the subsequent de-ionized water wetting process. To minimize the risks of oxidation, a water-based no-clean flux may be considered as an alternative to deionized water wetting following plasma surface activation. The adsorbed water molecules, in turn, bring in high-density OH (hydroxyl) groups, facilitating precision pre-bonding. Following PI surface activation and wetting, PI-to-PI hybrid bonding can occur at a relatively low temperature of 250° C. for only a few minutes. Key parameters for successful bonding include dishing of metal contacts, plasma activation time, volume of water introduced, bonding temperature, applied pressure, and bonding time.

Furthermore, oxide-to-oxide bonding requires high component flatness and surface cleanliness to prevent electrical interconnection failures resulting from the high hardness and poor deformation characteristics of SiO₂. In contrast to conventional oxide-to-oxide bonding, PI-to-PI bonding accommodates higher surface roughness and is more tolerant of component flatness due to the low modulus and more compliant characteristics of PIs, although optimal yield may necessitate external pressure. However, for ultra-fine pitch applications, oxide-to-oxide bonding is preferred over polyimide-to-polyimide bonding. Besides oxide and polyimide, other bonding materials that facilitate van der Waals self-aligned bonding or other types of chemical bonding can also be utilized.

In some embodiments, in contrast to the LALF process shown in FIGS. 8A to 8D, bonding of micro-LEDs to the receiving substrate can also be achieved by wafer-to-wafer mass transfer (W2WM) involving wafer-to-substrate bonding through wafer-to-wafer alignment and contact and whole-wafer laser scanning. This approach, akin to laser lift-off used in wafer-level fan-out packaging, facilitates the transfer of intact micro-LEDs without resorting to the use of the multi-beam-mode laser, while keeping other considerations the same.

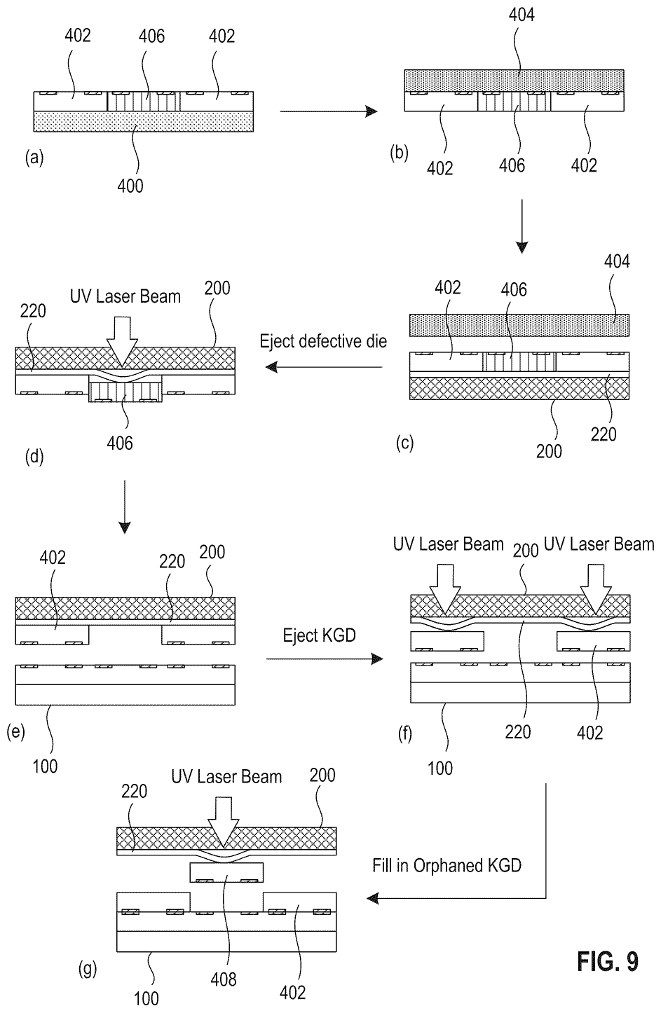

Referring to FIG. 9, in some embodiments, by leveraging the laser assisted mass transferring technique, a plurality of micro-LED dies 402, which may include one or more defective dies 406, can be transferred from a source substrate 400 to a tape substrate 404 through a tape transfer operation (see step (b) in FIG. 9), and then the plurality of micro-LED dies 402 on the tape substrate 404 can be transferred to a second substrate 200 with a release layer 220 (see step (c) in FIG. 9). Next, the defective dies 406 (e.g., micro-LEDs), can be ejected individually from the second substrate 200 by performing a first UV laser operation (e.g., a single-beam operation), for example (see step (d) in FIG. 9). Following defective die 406 removal from the second substrate 200, the second substrate 200 is then aligned with a first substrate 100 (e.g., a driver IC substrate, a display panel or a receiving substrate referred herein) and the same laser is then switched to the multi-beam mode by invoking the diffractive optical element using a x-y laser scanner to rapidly place good micro-LED dies 402 across a 10 to 300 μm gap onto the corresponding sites of the first substrate 100. As shown in step (f) in FIG. 9, the good micro-LED dies 402 are ejected from the second substrate 200 by performing a second UV laser operation through the backside of the second substrate 200 to generate gases that create a blister in the release layer 220, thereby enabling the downward force exerted by the blister along with the gravitational force to eject the good micro-LED dies 402 from the second substrate 200. Similar to the description provided to FIG. 8C, at least a good micro-LED dies 402 on the second substrate 200 is self-aligned to a corresponding site on the first substrate 100 when the dielectric portion of the good micro-LED die 402 on the first substrate 100 is in contact with the dielectric portion of the corresponding site of the second substrate 200 under room temperature. In other words, the second UV laser operation is performed prior to the self-alignment between the respective dielectric portions of at least a die region of the first substrate 100 and the corresponding sites of the second substrate 200. Subsequently, as shown in step (g) in FIG. 9, missing micro-LEDs are then filled in by aligning and ejecting orphaned good micro-LEDs 408 on the second substrate 200 onto the first substrate 100 by invoking the first UV laser operation. Compared to other LAMT approaches involving flip chip assembly of micro-LEDs, the disclosed LALF approach based on recessed bonding structures involving a soft metal section or a solder section, and self-aligned dielectric-to-dielectric bonding to rectify alignment issues can greatly enhance the chip placement yield as well as the bonding yield.

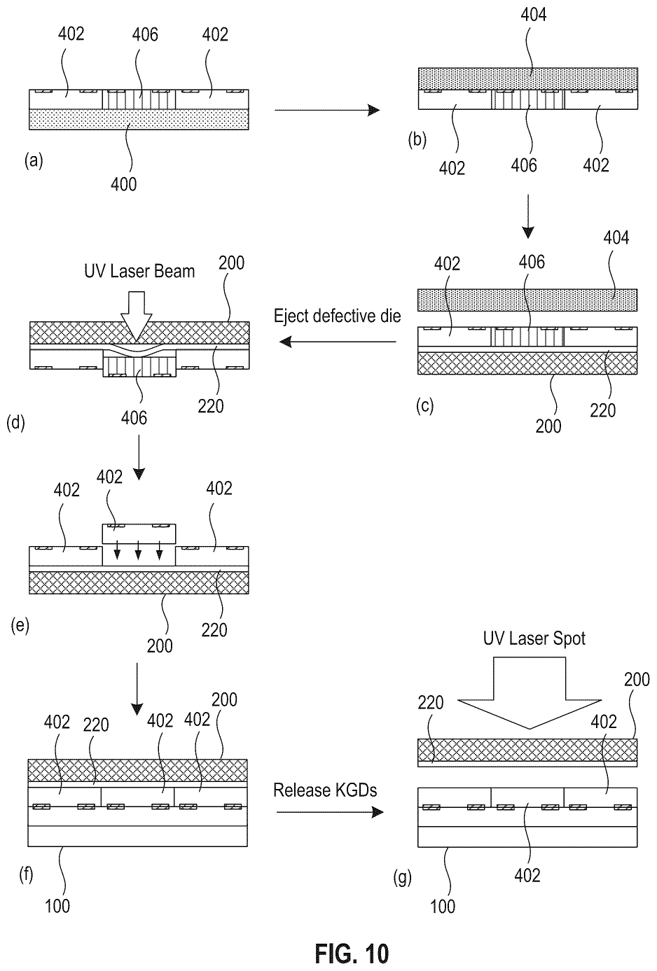

Referring to FIG. 10, the W2WM process is substantially similar to that of LALF as previously described in FIG. 9 with the exceptions that (1) the former requires replenishing known-good micro-LEDs on the sites of defective micro-LEDs (defective micro-LED ejected and now vacant sites) of the second substrate 200 prior to ejecting known-good micro-LEDs onto the first substrate 100 as shown in steps (d) and (e) in FIGS. 10; and (2) the former requires the use of a first substrate 100 reconstituted with only known-good chips/dies/sites using a fan-out like process—this is not required in the LALF approach because the W2WM process handles the bonding of chips/dies/sites on wafer-level instead of on individual die-level as is the case in LALF; and hence the replenished known-good micro-LEDs on the second substrate 200 and the reconstituted known-good chips/dies/sites on the first substrate 100 are required in the W2WM process to maximize the production yield. In addition, similar to the description provided to FIG. 8C, at least a good micro-LED die 402 on the second substrate 200 is self-aligned to a corresponding known-good-site on the first substrate 100 when the dielectric portion of the known-good micro-LED die 402 on the first substrate 100 is in contact with the dielectric portion of the corresponding known-good-site of the second substrate 200 under room temperature, as shown in step (f) in FIG. 10. Subsequently, a second UV laser operation, as illustrated in step (g) in FIG. 10, is performed to release the good micro-LED dies 402 from the second substrate 200 at once by using a conventional laser lift-off process which involves illuminating the second substrate 200 from the substrate side using a laser at a wavelength of, for instance, 355 nm to release the good micro-LED dies 402. The second UV laser operation referred in the process of W2WM illustrated in FIG. 10 can be a single-beam, a multi-beam operation, or a planar illumination over the entire substrate or wafer in consideration of production efficiency. In other words, the second UV laser operation (step (g) in FIG. 10) is performed after the self-alignment (step (f) in FIG. 10) between the respective dielectric portions of at least a die region of the first substrate 100 and the corresponding known-good-sites of the second substrate 200. Compared to other LAMT approaches involving flip chip assembly of micro-LEDs, the disclosed W2WM approach based on recessed bonding structures involving a soft metal section or a solder section, and self-aligned dielectric-to-dielectric bonding to rectify alignment issues can greatly enhance the chip placement yield as well as the bonding yield.

In the present disclosure, to achieve maximum placement accuracy and yield, one can also adjust process conditions and materials used in LAMT, LALF and/or W2WM. This includes the makeup and thickness of the release layer, laser conditions (and consequently the force exerted by the blister), and the gap between the micro-LED and the receiving substrate. These adjustments should align with the aforementioned dielectric-to-dielectric bonding conditions.

Moreover, for oxide-to-oxide bonding in the present disclosure, one can vary the oxide type and deposition technique, process conditions such as plasma gas, plasma power, surface roughness related to chemical mechanical polish (CMP), surface cleanliness, mono- to multiple layers of water molecules from de-ionized cleaning, bonding conditions (such as temperature and speed), and anneal conditions (e.g., anneal temperatures, anneal time, and the number of annealing steps) to achieve high-quality bonding and strong shear strength. In the case of wafer-to-wafer (W2W) bonding, the formation of voids caused by water droplet formation (due to the Joule-Thomson expansion effect) at the wafer edge during direct bonding can be prevented by controlling key parameters such as plasma conditions, surface roughness, degree of cleanliness, wafer warpage/flatness, and bonding conditions.

Going forward, in some embodiments of the present disclosure, a semiconductor package involving ultrafine pitches is revealed. The present disclosure involves utilizing recessed structures containing a soft metal section or a solder section, dielectric-to-dielectric bonding as well as laser assisted joining to enhance chip placement and bonding yields for structures involving ultrafine pitches and imperceptible dimensions. Although examples provided herein are based on micro-LEDs, the structures, processes and methodologies are equally applicable to other applications involving ultrafine pitches and imperceptible dimensions.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first die having a plurality of first metal pads at a first bonding side;
a second die over the first die, having a plurality of second metal pads at a second bonding side facing the first bonding side, wherein each of the first metal pads corresponds to each of the second metal pads with a pitch no greater than about 10 μm;
a first dielectric layer surrounding and in contact with a sidewall of the first metal pads; and
a second dielectric layer surrounding and in contact with a sidewall of the second metal pads.

2. The semiconductor package of claim 1, wherein the second die is a micro-LED die, a processor die, or a chiplet.

3. The semiconductor package of claim 1, wherein a dimension of the second die is less than about 10 μm by 10 μm.

4. The semiconductor package of claim 1, further comprising a soft metal (SM) section or a solder section between each of the first metal pads and the second metal pads, and a sidewall of the SM section or the solder section is in contact with the one of the first dielectric layer or the second dielectric layer, wherein a melting point of the SM section or the solder section is no greater than about 250° C.

5. The semiconductor package of claim 4, wherein the sidewall of the SM section or the solder section is aligned with a sidewall of one of the first metal pads or the second metal pads.

6. The semiconductor package of claim 4, wherein a first segment of a sidewall of the second dielectric layer proximal to the second die is in contact with a sidewall of the second metal pad, and a second segment of the sidewall of the second dielectric layer proximal to the first die is in contact with the sidewall of the SM section or the solder section.

7. The semiconductor package of claim 6, wherein a height ratio of the second segment and the first segment is in a range of from 25% to 85%.

8. The semiconductor package of claim 1, wherein the material of the first dielectric layer and the second dielectric layer comprises silicon dioxide or polymer.

9. A semiconductor package, comprising:
a first die;
a second die disposed over the first die; and
a bonding layer between the first die and the second die, the bonding layer comprises:
a plurality of first metal pads each stacked with a first barrier layer and connected to the first die, and a first dielectric bonding material contacting a sidewall of each of the plurality of first metal pads and a sidewall of the first barrier layer;
a plurality of second metal pads each stacked with a second barrier layer and connected to the second die, and a second dielectric bonding material contacting a sidewall of each of the plurality of second metal pads and a sidewall of the second barrier layer; and
a soft metal (SM) section or a solder section between each of the first metal pads and each of the second metal pads.

10. The semiconductor package of claim 9, wherein a thickness of each SM section or the solder section is in a range of from about 1 μm to about 2 μm.

11. The semiconductor package of claim 9, wherein the second die is a micro-LED die having a dimension less than about 10 μm by 10 μm, and the first die is a control IC die or a display panel configured to control the micro-LED die.

12. The semiconductor package of claim 9, wherein a pitch of the second metal pads is no greater than about 10 μm.

13. The semiconductor package of claim 9, wherein each of the first barrier layers and the second barrier layers comprises Ni, NiV, Ti, TiW, TiN, Ta, TaN, Cr, phased Cr/Cu, or their combinations, and each of the first barrier layers or the second barrier layers is coated with a wetting layer comprising Au, Ag, Pd, or a combination of metals comprising Cu, Ni, NiV, Au, or Ag, while the SM section or the solder section comprises a die attachment materials made up of Sn, Pb, Au, Ag, Cu, In, Bi, Zn, Al, thorium, or their combinations, and the material of the first metal pads and the second metal pads include Cu, Au, Al, W, Mo, Rh, Co, Ru, Ir, Pt, Pd, Os or combinations thereof.

14. A method for manufacturing a semiconductor package, the method comprising:
receiving a first substrate and a second substrate;
forming a first bonding layer on the first substrate comprising:
a plurality of first dielectric bonding blocks and a plurality of first metal pads laterally and alternatively arranged with the plurality of first dielectric bonding blocks; and
a plurality of first soft metal (SM) or solder layers, each over one of the first metal pads, wherein an upper surface of the first SM or solder layer is recessed from an upper surface of the first dielectric bonding blocks;
forming a second bonding layer on the second substrate, wherein the second bonding layer comprises a plurality of second dielectric bonding blocks and a plurality of second metal pads laterally and alternatively arranged with the plurality of second dielectric bonding blocks;
self-aligning at least a die region on the second substrate to a corresponding die region on the first substrate by aligning and contacting the first dielectric bonding blocks to the second dielectric bonding blocks under room temperature; and
elevating a temperature of the plurality of first SM or solder layers by performing a laser heating operation.

15. The method of claim 14, wherein the second bonding layer further comprises a plurality of second SM or solder layers, each over one of the second metal pads, wherein an upper surface of the second SM or solder layers is recessed from an upper surface of the second dielectric bonding blocks prior to the self-aligning operation.

16. The method of claim 14, further comprising:
performing a non-laser heating operation to the semiconductor package to achieve a permanent bonding between the first substrate and the second substrate after elevating the temperature of the plurality of first SM or solder layers by the laser heating operation.

17. The method of claim 16, wherein the non-laser heating operation comprises applying an external pressure.

18. The method of claim 14, wherein performing the laser heating operation comprises directing an infrared (IR) laser to heat the first SM or solder layers.

19. The method of claim 14, further comprising:
transferring a plurality of micro-LED dies from a source substrate to a tape substrate through a tape transfer operation;
transferring the plurality of micro-LED dies on the tape substrate to the second substrate with a release layer;
ejecting a defective micro-LED die from the second substrate by performing a first ultraviolet (UV) laser operation; and
ejecting a known-good micro-LED die from the second substrate towards the first substrate by performing a second UV laser operation prior to the self-alignment operation.

20. The method of claim 14, further comprising:
transferring a plurality of micro-LED dies from a source substrate to a tape substrate through a tape transfer operation;
transferring the plurality of micro-LED dies on the tape substrate to the second substrate with a release layer;
ejecting a defective micro-LED die from the second substrate by performing a first ultraviolet (UV) laser operation; and
releasing known-good micro-LED dies from the second substrate and placing them on the first substrate by performing a second UV laser operation after the self-alignment operation.
